(19) United States
(12) Patent Application Publication
(10) Pub. No.: US 2014/0061921 A1
(43) Pub. Date: Mar. 6, 2014

(54) GOLD BONDING IN SEMICONDUCTOR DEVICES USING POROUS GOLD

(71) Applicant: Nagesh Basavanhally, Skillman, NJ (US)

(72) Inventor: Nagesh Basavanhally, Skillman, NJ (US)

(73) Assignee: Alcatel-Lucent USA, Incorporated, Murray Hill, NJ (US)

(21) Appl. No.: 13/604,080

(22) Filed: Sep. 5, 2012

(51) Int. Cl. H01L 21/28; H01L 23/48

(52) U.S. Cl. 257/753; 438/654; 257/E21.158; 257/E23.01

(57) ABSTRACT

A method of manufacturing comprising providing a semiconductor layer having metal adhesion layer on a planar surface of the semiconductor layer and an alloy layer on the metal adhesion layer, the alloy layer comprising an alloy of gold and a non-gold metal. The method comprises removing a portion of the non-gold metal from the alloy layer to form a porous gold layer. The method comprises applying pressure between the porous gold layer and a metal layer to form a bond between the semiconductor layer and the metal layer.

### TECHNICAL FIELD

The invention relates to in general, semiconductor devices methods for manufacturing the same.

### BACKGROUND

This section introduces aspects that may help facilitate a better understanding of the inventions. Accordingly, the statements of this section are to be read in this light and are not to be understood as admissions about what is prior art or what is not prior art.

A semiconductor component may be heated to high temperatures, e.g., temperatures of about 150° C. or higher) during the solder bonding of the semiconductor component to another component during a device's fabrication. The mismatch between the coefficient of thermal expansion of the semiconductor component and the other component can, during bonding, impart residual stress in the semiconductor component.

### SUMMARY

One embodiment is a method of manufacturing. The method comprises providing a semiconductor layer having metal adhesion layer on a planar surface of the semiconductor layer and an alloy layer on the metal adhesion layer, the alloy layer comprising an alloy of gold and a non-gold metal. The method comprises removing a portion of the non-gold metal from the alloy layer to form a porous gold layer. The method comprises applying pressure between the porous gold layer and a metal layer to form a bond between the semiconductor layer and the metal layer.

In some embodiments, the metal layer is a conductive line or a substrate of a semiconductor device. In some embodiments, the metal layer is a second metal adhesion layer located on a planar surface of a second semiconductor layer. Any of the above embodiments further include forming the second metal adhesion layer on the planar surface of the second semiconductor layer, wherein the applying pressure further includes causing the porous gold layer to contact the second adhesion layer. In some such embodiments, the metal layer is a second porous gold layer located on a planar surface of a second semiconductor layer. Some such embodiments of the method further includes forming the second metal adhesion layer on the second semiconductor layer, forming a second alloy layer on the second metal adhesion layer, the second alloy layer comprising an alloy of gold and a non-gold metal, and removing a portion of the non-gold metal from the second alloy layer to form a second porous gold layer on the second metal adhesion layer. In such embodiments, the applying pressure includes causing the porous gold layer to contact the second porous gold layer. In any of the above embodiments, applying the pressure includes a producing a pressure between the porous gold and the metal layer of about 600 MPa or less for about 60 seconds or less. In any of the above embodiments, applying the pressure is performed at a temperature of about 100° C. or less. In some embodiments, the non-gold metal of the alloy layer includes one or more of silver, zinc, nickel, aluminum, or platinum. In some embodiments, the non-gold metal is silver. In some embodiments, the alloy layer has about 20 to about 50 weight percent gold and has a remainder substantially of silver. In some embodiments, wherein the adhesion layer includes a layer of titanium or chromium on the semiconductor layer. In some such embodiments, the adhesion layer includes a second layer of gold or platinum on the first layer. In some such embodiments, the adhesion layer includes a third layer of gold on the second layer of platinum.

Another embodiment is a semiconductor device. The device comprises a semiconductor layer having a metal adhesion layer bonded to a planar surface thereof, a porous gold layer bonded to the metal adhesion layer and a gold bond between a metal layer and the porous gold layer.

In any of the above embodiments of the device, the semiconductor layer is one of silicon, lithium niobate or a III-V semiconductor. In some embodiments, the gold bond is part of an electrical interconnection to an electrical component on the semiconductor layer. In some embodiments, the gold bond is part of flip-chip bond between a bond pad of the semiconductor layer and the metal layer on a substrate of the device.

Another embodiment is a semiconductor device. The device comprises a semiconductor layer having a planar surface with a metal adhesion layer thereon, a metal layer and a gold bond between the metal adhesion layer and the metal layer. The gold bond includes a non-porous gold interface region adjacent the metal layer, the interface region being composed of non-porous gold. The gold bond also includes a porous gold region adjacent the metal adhesion layer.

In some such embodiments, the porous gold region includes a plurality of pillars of gold which are each substantially perpendicularly oriented with respect to the planar surface.

### BRIEF DESCRIPTION OF THE DRAWINGS

The embodiments of the disclosure are best understood from the following detailed description, when read with the accompanying FIGUREs. Some features in the figures may be described as, for example, “top,” “bottom,” “vertical” or “lateral” for convenience in referring to those features. Such descriptions do not limit the orientation of such features with respect to the natural horizon or gravity. Various features may not be drawn to scale and may be arbitrarily increased or reduced in size for clarity of discussion. Reference is now made to the following descriptions taken in conjunction with the accompanying drawings, in which:

FIG. 1A presents a flow diagram of an example method of manufacturing a semiconductor device of the disclosure, such as any of the example devices described in the context of FIGS. 2-10;

FIG. 1B presents a flow diagram of an example method of manufacturing of the disclosure, such as manufacturing for any of the example devices described in the context of FIGS. 2-10;

FIG. 2 shows a cross-sectional view of an example semiconductor device of the disclosure after forming a metal adhesion layer on a semiconductor layer and an alloy layer of gold and a non-gold metal on the metal adhesion layer;

FIG. 3 shows a cross-sectional view of an example semiconductor device of the disclosure after selectively removing the non-gold metal from the alloy layer to produce a porous gold layer, e.g., a nanoporous gold layer;

FIG. 4 shows a cross-sectional view of an example semiconductor device of the disclosure after applying pressure to bond the porous gold layer and a metal layer;

FIG. 5 shows a cross-sectional view of an example semiconductor device of the disclosure after depositing a second metal adhesion layer 510 on a second semiconductor layer;

FIG. 6 shows a cross-sectional view of an example semiconductor device of the disclosure after pressing the first semiconductor layer and second semiconductor layer together such that the porous gold layer contacts the second adhesion layer, e.g., thereby forming a gold bond;

FIG. 7 shows a cross-sectional view of an example semiconductor device of the disclosure after depositing a second metal adhesion layer on a second semiconductor layer, and depositing a second gold non-gold metal alloy layer on the second metal adhesion layer;

FIG. 8 shows a cross-sectional view of an example semiconductor device of the disclosure after selectively removing the non-gold metal from the second alloy layer to produce a second porous gold layer, e.g., a nanoporous gold layer; and

FIG. 9 shows a cross-sectional view of an example semiconductor device of the disclosure after pressing the first semiconductor layer and second semiconductor layer together such that the porous gold layer contacts the second porous gold layer, thereby forming the gold bond; and

FIG. 10 depicts a detailed cross-sectional view of an expanded portion of an example gold bond, corresponding to view 10 in FIG. 4.

In the Figures and text, similar or like reference symbols indicate elements with similar or the same functions and/or structures.

In the Figures, the relative dimensions of some features may be exaggerated to more clearly illustrate one or more of the structures or features therein.

Herein, various embodiments are described more fully by the Figures and the Detailed Description. Nevertheless, the inventions may be embodied in various forms and are not limited to the embodiments described in the Figures and Detailed Description of Illustrative Embodiments.

### DETAILED DESCRIPTION

The description and drawings merely illustrate the principles of the inventions. It will thus be appreciated that those skilled in the art will be able to devise various arrangements that, although not explicitly described or shown herein, embody the principles of the inventions and are included within its scope. Furthermore, all examples recited herein are principally intended expressly to be for pedagogical purposes to aid the reader in understanding the principles of the inventions and concepts contributed by the inventor(s) to furthering the art, and are to be construed as being without limitation to such specifically recited examples and conditions. Moreover, all statements herein reciting principles, aspects, and embodiments of the inventions, as well as specific examples thereof, are intended to encompass equivalents thereof. Additionally, the term, “or,” as used herein, refers to a non-exclusive or, unless otherwise indicated. Also, the various embodiments described herein are not necessarily mutually exclusive, as some embodiments can be combined with one or more other embodiments to form new embodiments.

As part of the present disclosure, it was discovered that porous gold (e.g., nanoporous gold) can be used to rapidly form gold bonds (e.g., gold compression bonds) to semiconductor materials at low temperature. As further illustrated in the example embodiments to follow, the formation of a porous gold layer can be integrated into standard semiconductor processes to facilitate the formation of a gold compression bond at low temperatures to thereby mitigate temperature-induced stress formation in some semiconductor materials. Although particularly useful for forming gold bonds to semiconductor material, such a lithium niobate, that are sensitive to temperature-induced stress formation, the rapid speed of bond formation can be useful for forming gold bonds to broad range of semiconductor materials.

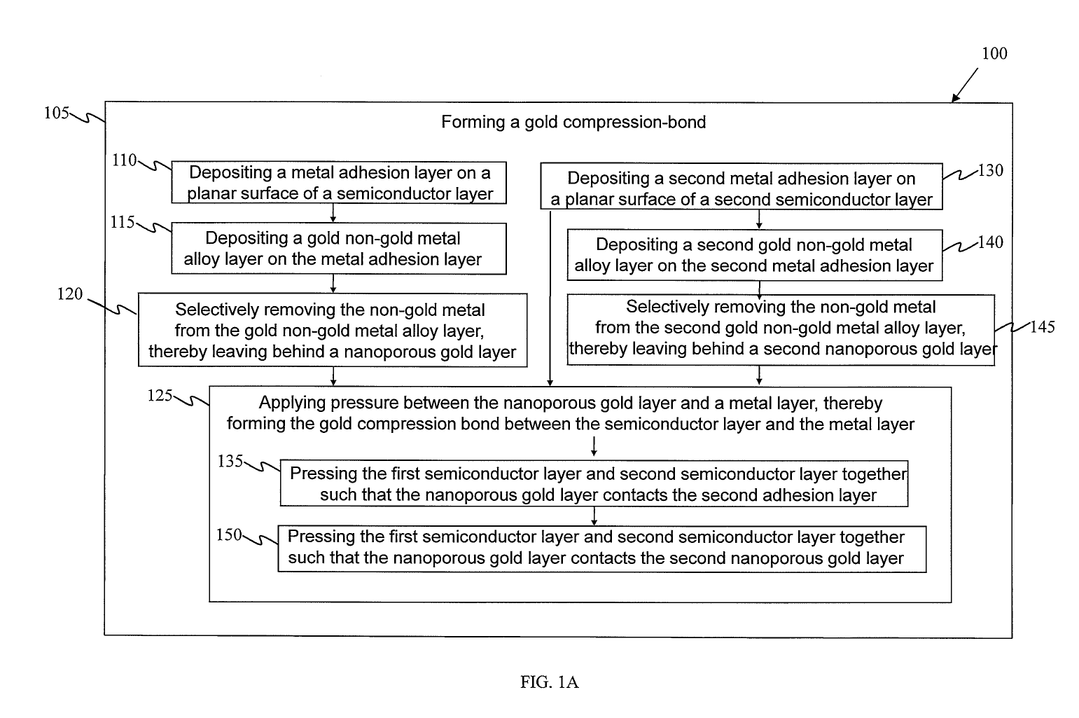

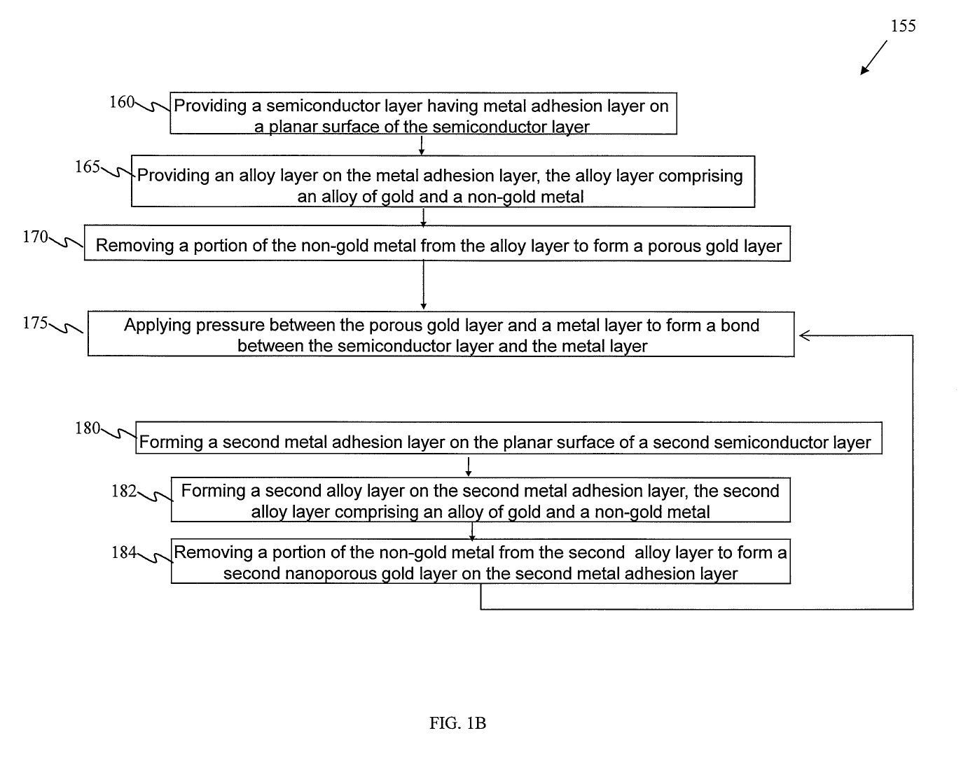

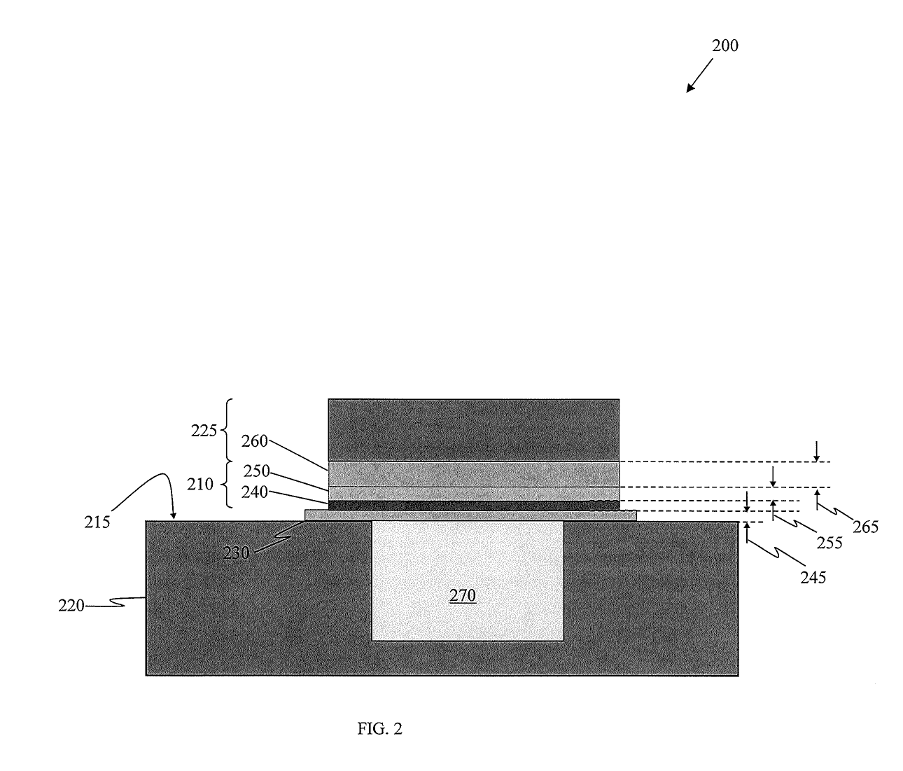

One embodiment of the disclosure is a method of manufacturing a semiconductor device. FIG. 1A presents a flow diagram of an example method 100 of manufacturing a semiconductor device of the disclosure. FIG. 1B presents a flow diagram of an example method 155 of manufacturing of the disclosure. FIGS. 2-10 show cross-sectional views of an example semiconductor device 200 made at different stages of completion, in accordance with selected steps of the method 100 presented in FIG. 1A or 1B.

With continuing reference to FIG. 1A throughout the example method 100 comprises a step 105 of forming a gold bond such as a gold compression-bond. One of ordinary skill would understand that a compression bond refers to the bond between to metal layers formed by applying a force and heat simultaneously to bring the metal atoms of the two metal layers into atomic contact, such as implemented from any one of: diffusion bonding, pressure joining, thermocompression welding or solid-state welding as applied in the semiconductor device fabrication processes.

As illustrated in FIG. 2, forming the gold compression-bond in accordance with step 105 includes a step 110 of depositing a metal adhesion layer 210 on a planar surface 215 of a semiconductor layer 220, and a step 115 of depositing a gold non-gold metal alloy layer 225 on the metal adhesion layer 210.

The semiconductor layer 220 can be a diced semiconductor substrate layer or a semiconductor chip or a pre-diced wafer layer. In some cases the semiconductor layer 220 is composed of lithium niobate, silicon, a III-V compound semiconductor, or other semiconductor layers using in electronic, optical or optoelectronic semiconductor devices 200. One of ordinary skill in the art would understand that an adhesion layer is a metallic layer (such as titanium or chromium) that improves the adherence of an overlying metal layer (e.g., a layer of gold or platinum) to a semiconductor layer (e.g., a silicon layer).

The non-gold metal can be any metal that can form an alloy with gold and that can be selectively removed from the gold non-gold alloy layer 225 without removing the gold. In some embodiments, the non-gold metal includes one or more of silver, zinc, nickel, aluminum, platinum or chemically dissolvable constituent elements. In some embodiments, the gold non-gold alloy layer 225 the gold-other metal alloy layer 225 is substantially composed of a gold silver alloy layer (e.g., the layer 225 has less than 1 weight percent layer 225 of metals other than gold or silver). In some embodiments the wherein the gold non-gold metal alloy layer 225 includes about 20 to about 50 weight percent gold and balance silver, and in some cases about 35 weight percent gold and balance silver.

One of ordinary skill in the art would be familiar with various metal deposition processes such as thermal evaporation, sputtering evaporation or electro-plating, to deposit the metal adhesion layer 210 and gold non-gold metal alloy layer 225. In some cases, as illustrated in FIG. 2, the adhesion layer 210 and non-gold metal alloy layer 225 thereon are deposited on bond pads 230 of the semiconductor layer 220. One skilled in the art would understand how to deposit a photoresist layer, pattern the photoresist layer to form openings over the bond pads 230, deposit the metal adhesion layer 210 and non-gold metal alloy layer 225 through the opening.

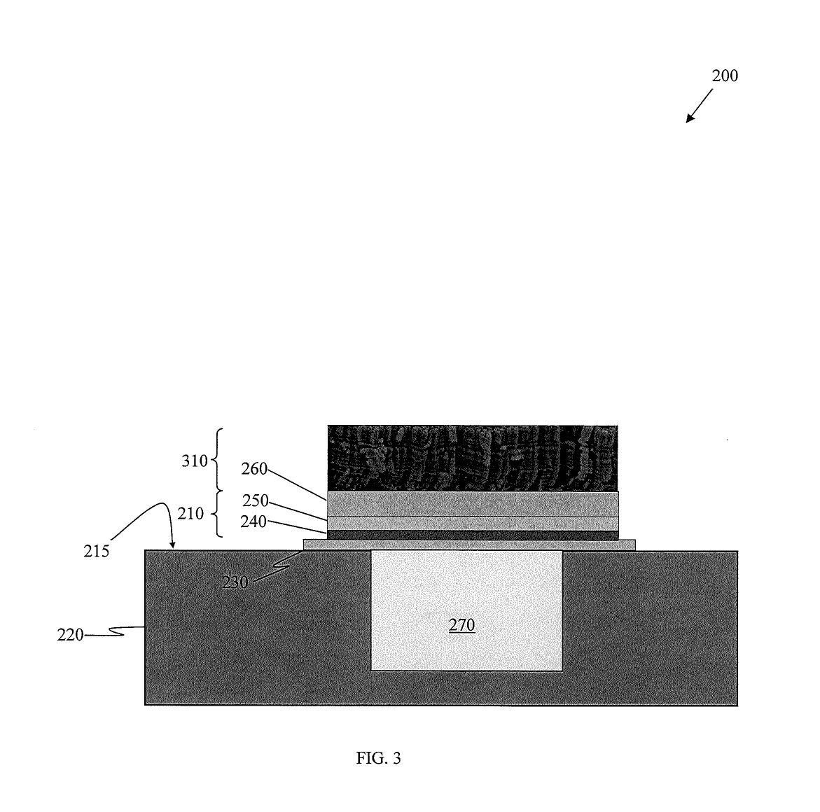

As illustrated in FIG. 3, forming the gold compression-bond 205 in accordance with step 105 also includes a step 120 of selectively removing the non-gold metal from the gold non-gold metal alloy layer 225 (FIG. 2), thereby leaving behind a nanoporous gold layer 310. For instance, in some cases selectively removing the other metal from the gold non-gold metal alloy layer 225 includes exposing the semiconductor layer 220 having the gold non-gold metal alloy layer 225 thereon to nitric acid to thereby dissolve the non-gold metal. For instance, in some cases the semiconductor layer 220 having gold non-gold metal alloy layer 225 (e.g., a gold silver alloy layer) thereon is submerged in an aqueous solution of concentrated nitric acid (e.g., a nitric acid concentration in a ranges of about 10 wt % to 70 wt %) for about 1 to 5 minutes, depending upon the particular concentration used.

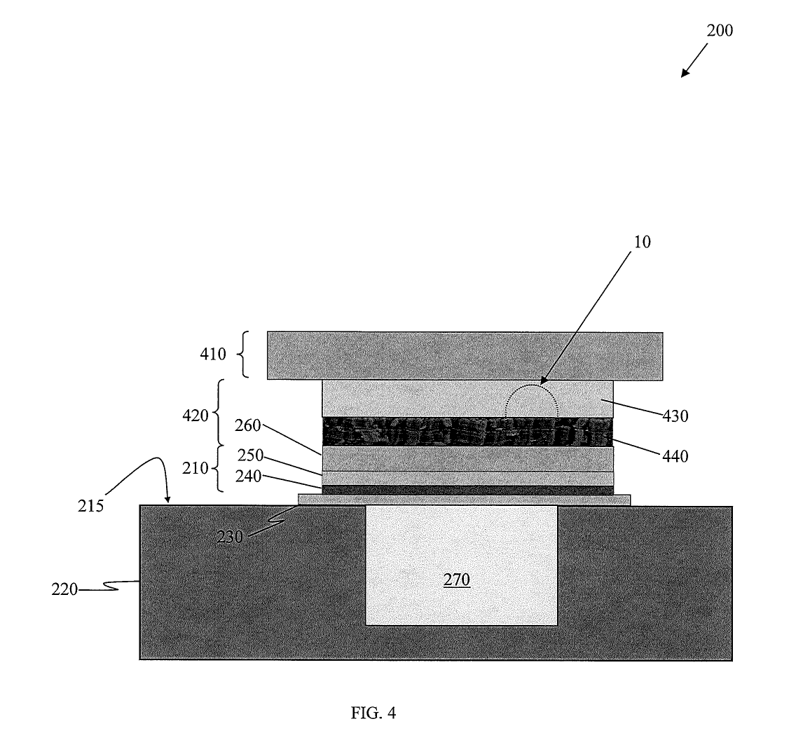

As illustrated in FIG. 4, forming the gold compression-bond 205 in accordance with step 105 also includes a step 125 of applying pressure between the nanoporous gold layer 310 (FIG. 3) and a metal layer 410, thereby forming the gold compression bond 420 between the semiconductor layer 210 and the metal layer 410. For instance, in some cases applying the pressure can include applying a substantially vertical pressure (e.g., perpendicular to the planar surface 215) between the two layers 310, 410. In some cases, applying the pressure can include applying a substantially horizontal pressure (e.g., parallel to the planar surface 215) between the two layers 310, 410. In some cases, both vertical and horizontal pressure can be applied as part of step 125. For instance, to facilitate forming the compression bond, vertical pressure between the layers 310, 410 can be applied at the same time as one or both of the layers 310, 410 are moved parallel to the planar surface 215 in a scrubbing motion.

For example, in some cases, applying the pressure in step 125 includes a pressure between the nanoporous gold 310 and the metal layer 410 of about 600 MPa or less for about 60 s or less, and in some case a pressure of about 2800 to 320 MPa for about 25 to 35 seconds. In some cases, applying the pressure in step 125 is performed at a temperature of about 100° C. or less, and in some cases, about 25° C. or less. Applying the pressure in accordance to step 125 as such low temperatures helps to avoid temperature induced stresses in the semiconductor layer, such as a lithium niobate layer.

Applying the pressure in accordance to step 125 to form the gold compression bond 420 is advantageous over some bonding process that require plasma irradiation process to activate the surface prior to or during the step of applying the pressure. That is, step 125 can be performed in a plasma-free environment. Still, in some cases, surface cleaning such as plasma enhanced or back sputter cleaning, which is well known in semiconductor industry can be desirable prior to bonding to eliminate surface contaminants. Such surface cleaning procedures can be applied to planar surface 215 of the semiconductor layer 220, the metal adhesion layer 210, the nanoporous gold layer 310 or the metal layer 410 before depositing and forming these layers or before forming the gold compression bond 420.

In some cases, such as illustrated in FIG. 4, the metal layer 410 can be a substrate of the device 200, while in other cases the metal layer can be a conductive line (e.g., a copper line) located on a substrate, such as a print circuit board.

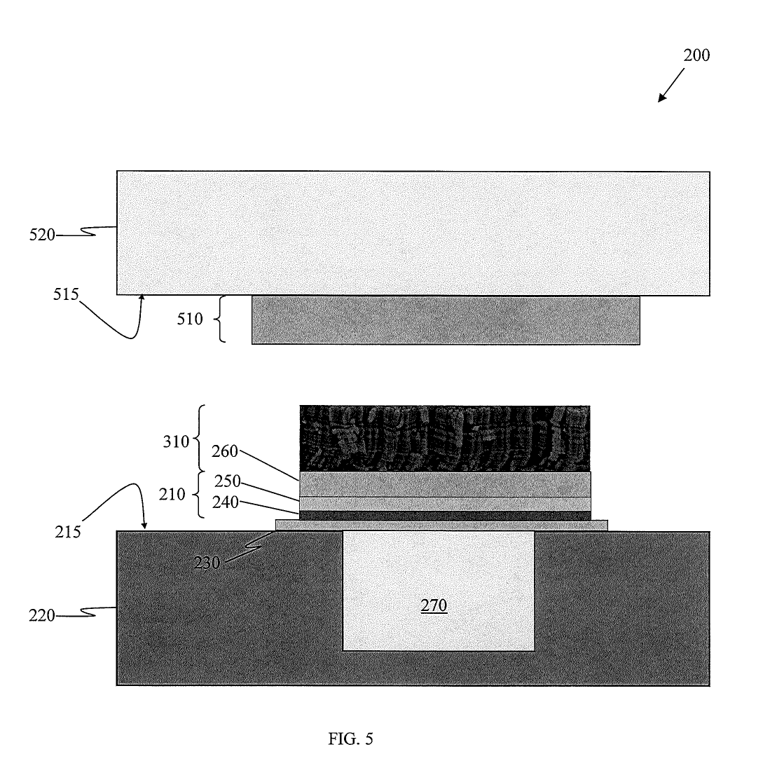

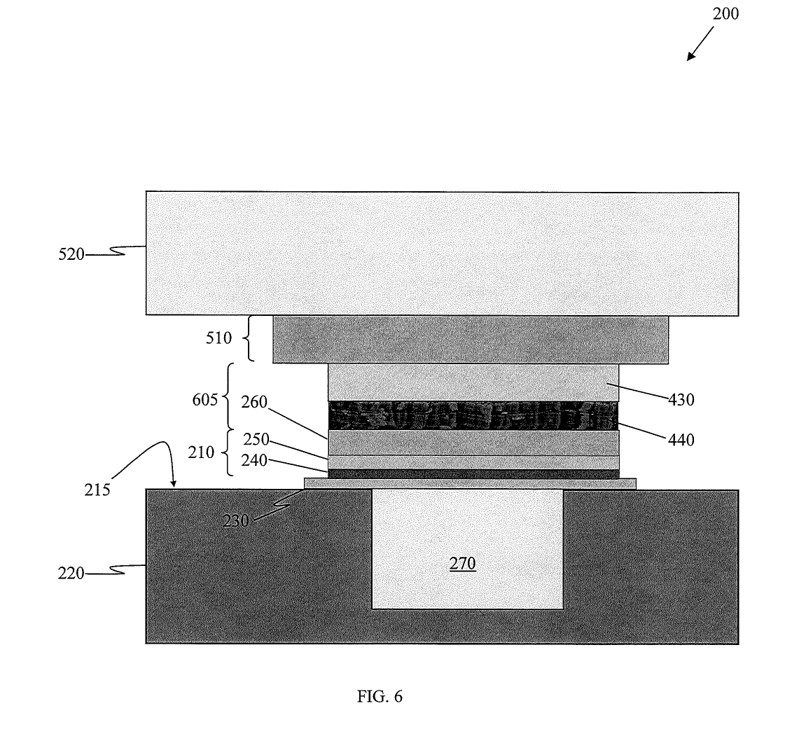

In still other cases, such as illustrated in FIG. 5, the metal layer can be a second metal adhesion layer 510 that is located on a planar surface 515 of a second semiconductor layer 520. In some such embodiments, the method 100 can further include a step 130 of depositing a second metal adhesion layer 510 on the planar surface 515 of the second semiconductor layer 520. In such cases, as illustrated in FIG. 6, applying pressure between the nanoporous gold layer 310 (FIG. 3) and the metal layer 510 in accordance with step 125 can further include a step 135 of pressing the first semiconductor layer 220 and second semiconductor layer 520 together such that the nanoporous gold layer 310 (FIG. 3) contacts the second adhesion layer 510, thereby forming the gold compression bond 605.

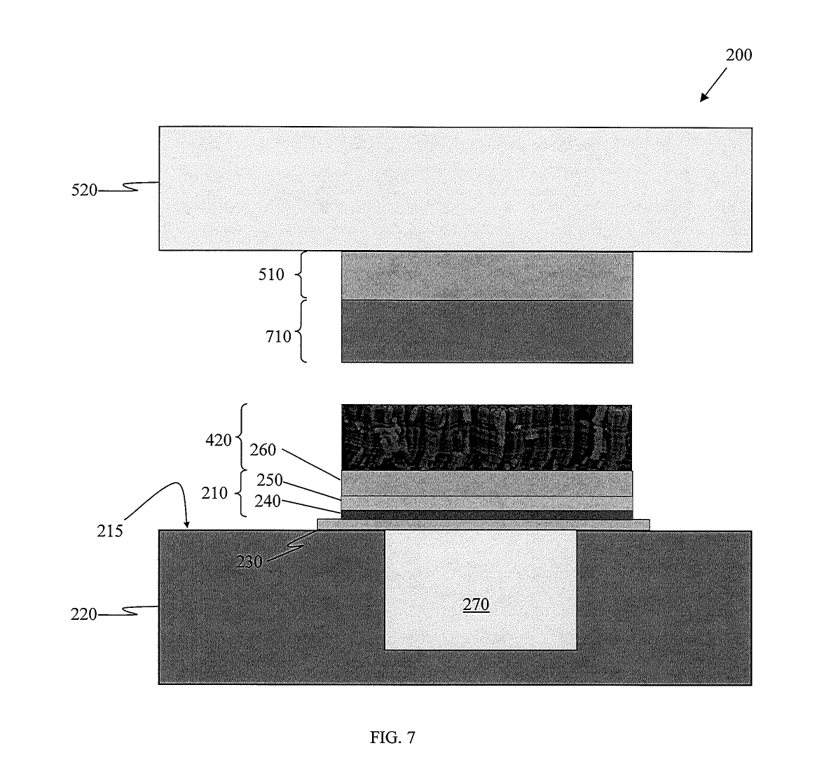

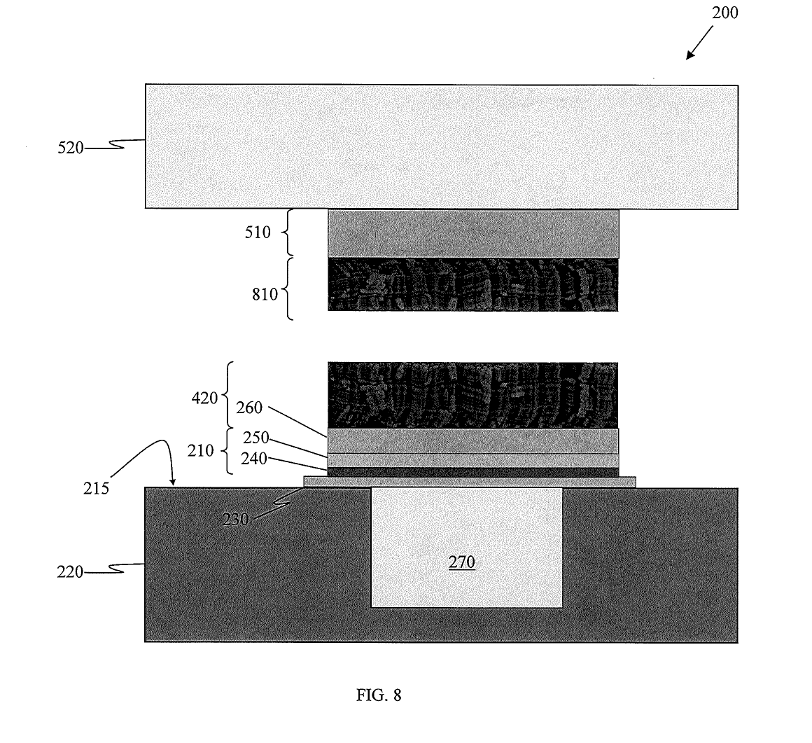

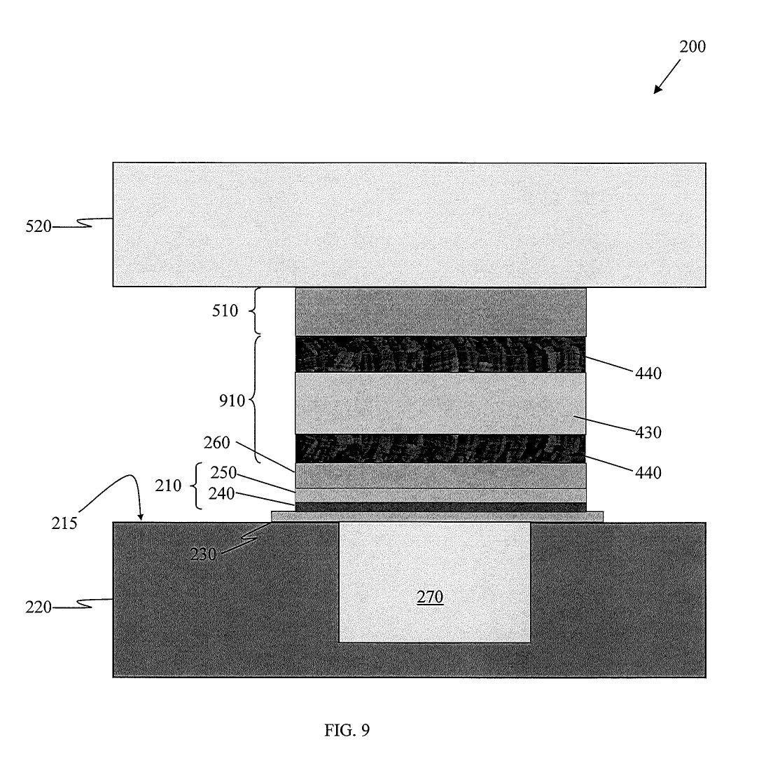

In yet other cases, such as illustrated in FIG. 7, the metal layer can be a second nanoporous gold layer located on the planar surface 515 of the second semiconductor layer 520. For example, consider an embodiment where the first semiconductor layer 220 can be composed of one or silicon or lithium niobate and the second semiconductor layer 520 can composed of the other of the other of silicon or lithium niobate. In some such embodiments, as illustrated in FIG. 7, the method 100 can further include the step 130 of depositing the second metal adhesion layer 510 on the planar surface 515 of the second metal adhesion layer 510, and, a step 140 forming a second gold non-gold metal alloy layer 710 on the second metal adhesion layer 510. As illustrated in FIG. 8, the method 100 can also include step 145 of selectively removing the non-gold metal from the second gold non-gold metal alloy layer 710 (FIG. 7), thereby leaving behind a second nanoporous gold layer 810 on the second metal adhesion layer 510. In some such cases, as illustrated in FIG. 9, applying pressure between the nanoporous gold layer 310 (FIG. 3) and the metal layer 810 (FIG. 8), in accordance with step 125, can further include a step 150 of pressing the first semiconductor layer 220 and second semiconductor layer 520 together such that the nanoporous gold layer 310 (FIG. 3) contacts the second nanoporous gold layer 810 (FIG. 8), thereby forming the gold compression bond 910.

With continuing reference to FIGS. 1-9 throughout, in some embodiments, the step 110 of depositing the adhesion layer 210, or the step 130 of depositing the second adhesion layer 510, includes depositing a titanium or chromium layer 240 on the semiconductor layer 220 (or second layer 520). Titanium or chromium can advantageously form strong bonds to semiconductor material, such as silicon or lithium niobate, and thereby help prevent the gold compression bond formed thereon from pealing off of the semiconductor layer 220. In some cases, the layer 240 has a thickness 245 in a range of about 0.05 to 0.2 microns. In some such embodiments, the nanoporous gold layer 310 (or layer 810) can directly contact this layer 240 (or equivalent layer in layer 510).

In other embodiments, depositing the adhesion layer or layers, in accordance with step 110 or step 130, includes depositing a second layer 250 of gold or platinum, on the first layer 240. In some cases, the layer 250 has a thickness 255 in a range of about 0.1 to 4 microns. Such a second layer, composed of gold or platinum, can facilitate bonding of the gold non-gold metal alloy layer to the metal adhesion layer. In some such embodiments, the nanoporous gold layer 310 (or layer 810) can directly contact this second layer 250.

In still other embodiments, depositing the adhesion layer or layers, in accordance with step 110 or step 130, includes depositing a third layer 260 of gold on the second layer 250 of platinum. In some cases, the layer 250 has a thickness 265 in a range of about 0.2 to 10 microns, and in some cases about 0.5 to 2 microns. Such a third layer, composed of gold, can facilitate bonding of the non-gold metal alloy layer to the metal adhesion layer, while the second layer 250 of platinum can serve as a metal atom diffusion barrier. In some such embodiments, the nanoporous gold layer 310 (or layer 810) can directly contact this second layer 260 (or layer 550).

With continuing reference to FIG. 1B throughout, the example method 155 comprises, in step 160, providing a semiconductor layer 220 having metal adhesion layer 210 on a planar surface 215 of the semiconductor layer 220. The method 155 comprises, in step 165, providing an alloy layer 225 on the metal adhesion layer 210, the alloy layer 225 comprising an alloy of gold and a non-gold metal. The method 155 comprises, in step 170, removing a portion of the non-gold metal from the alloy layer 225 to form a porous gold layer 310. The method 155 comprises, in step 175, applying pressure between the porous gold layer 310 and a metal layer 410 to form a bond 420 between the semiconductor layer 220 and the metal layer 410.

In some embodiments, the metal layer 410 is a conductive line or a substrate of a semiconductor device 200. In some embodiments, the metal layer is a second metal adhesion layer 510 located on a planar surface 515 of a second semiconductor layer 520. In some embodiments the method 155, further includes a step 180 of forming a second metal adhesion layer 510 on the planar surface 515 of the second semiconductor layer 520, wherein the applying pressure (step 175) further includes causing the porous gold layer 310 to contact the second adhesion layer 510. For instance, in some such embodiments the method 155 further includes the step 180 of forming the second metal adhesion layer 510 on the second semiconductor layer 520, a step 182 of forming a second alloy layer 710 on the second metal adhesion layer 510, the second alloy layer 710 comprising an alloy (e.g., a second alloy composition) of gold and a non-gold metal, and, a step 184 of removing a portion of the non-gold metal from the second alloy layer 710 to form a second porous gold layer 810 on the second metal adhesion layer 510. In such embodiments, the applying pressure step 175 includes causing the porous gold layer 310 to contact the second porous gold layer 180. In any of the above embodiments, applying the pressure in step 175 includes a producing a pressure between the porous gold 180 and the metal layer (e.g., any of layers 410, 510 or 810) of about 600 MPa or less for about 60 seconds or less. In any of the above embodiments, applying the pressure in step 175 is performed at a temperature of about 100° C. or less. In some embodiments, the non-gold metal of the alloy layer 225 (or second alloy layer 710) includes one or more of silver, zinc, nickel, aluminum, or platinum. In some embodiments, the non-gold metal is silver. In some embodiments, the alloy layer 225 (or second alloy layer 710) has about 20 to about 50 weight percent gold and has a remainder substantially of silver. In some embodiments, the adhesion layer 210 (or second adhesion layer 510) includes a layer 240 (e.g., a first layer) of titanium or chromium on the semiconductor layer 220. In some such embodiments, the adhesion layer 225 can include a second layer 250 of gold or platinum on the first layer 240. In some such embodiments, the adhesion layer 210 includes a third layer 260 of gold on the second layer 250 of platinum.

Another embodiment of the disclosure is a semiconductor device that comprises the gold compression bond manufactured by any of the embodiments of the disclosed methods. For instance, the device can be any of the semiconductor devices 200 which include any of the embodiments of the gold compression bond 420, 605, 910 such as presented in FIGS. 2-9 and manufactured in accordance to the method steps discussed in context of FIG. 1.

The device 200 can include any of the components parts discussed in the context of FIGS. 1-9. For instance, in some cases, the semiconductor layer is composed of one of silicon, lithium niobate or a III-V semiconductor. For instance, in some cases the semiconductor layer 220 is composed of one of silicon or lithium niobate, and, the second semiconductor layer 520 is composed of the other of silicon or lithium niobate.

In some embodiments, the gold compression bond (e.g., any of bonds 420, 605, 910) can be a material bond that couples two component parts of the device 200 together. For instance, in some cases, the semiconductor layer 220 can be a silicon substrate having an optical fiber thereon, and the second semiconductor layer 520 can be a lithium niobate optical chip that is bonded to the silicon substrate, via one or more of the gold compression bonds 420, 605, 910, and thereby be aligned with the optical fiber.

In other embodiments, the gold compression bond is part of an electrical interconnection bond permitting the transmission of a signal between an component 270 (e.g., a logic or analog electronic circuits, an optoelectronic devices, microelectromechanical systems, spatial light modulators or other components of a telecommunications system) on the semiconductor layer 220 and the metal layer (e.g., any of layers 410, 520, 810) which, in turn, can be electrically coupled to another component of the device 200 or a difference device. For instance, in some cases, the gold compression-bond 420, 605, 910 can be part of flip-chip bond between a bond pad 230 of the semiconductor layer 220 and the metal layer (e.g., second adhesion layer 510) on a substrate (e.g., second layer 520) of the device 200.

Still another embodiment of the disclosure is a semiconductor device, such as any of the example devices 200 discussed in the context of FIGS. 1-10.

For instance, the semiconductor device 200 comprises a semiconductor layer 220 having a planar surface 215 with a metal adhesion layer 210 thereon, a metal layer (e.g., any of layers 410, 520, 810) and a gold compression bond (e.g., any of bonds 420, 605, 910). As further illustrated in FIGS. 4, 6 and 9, the gold compression bond includes an non-porous gold interface region (e.g., region 430) adjacent the metal layer, the interface region being composed of non-porous (i.e., solid gold that is substantially devoid of pores therein). The gold compression bond can also include a nanoporous gold remnant region (e.g., region 440) adjacent the metal adhesion layer 210 (or second metal adhesion layer 510), the remnant region including a nanoporous gold layer.

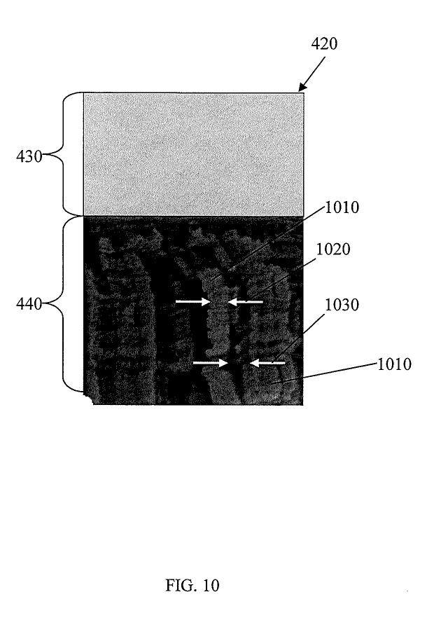

FIG. 10 depicts a detailed cross-sectional view of an expanded portion of an example gold compression bond 410, corresponding to view 10 in FIG. 4, although analogous features can be also present for the gold compression bonds depicted in FIG. 6 or 9. As illustrated in FIG. 10, in some embodiments of the device 200, the non-porous gold interface region 430 is substantially solid gold having no porous therein. As further illustrated in FIG. 10, the nanoporous gold remnant region 440 can have a plurality of pillars 1010 of gold which are each substantially perpendicularly oriented with respect to the planar surface 215 of the semiconductor layer 220 (FIG. 4) and each of the pillars 1010 having a thickness 1020 in a range of about 0.1 to 0.3 microns, and, a separation distance 1030 between adjacent pillars in a range about 0.01 to 0.03 microns. One of ordinary skill would appreciate how the thickness 1020 and separation distance 1030 would vary depending upon the gold non-gold metal alloy used, the procedure used to remove the non-gold metal (e.g., in step 120), and the temperature and pressure applied to form the gold compression bond in step 125 (or steps 135 or 145).

Another embodiment is another semiconductor device. With continuing reference to FIGS. 2-10, the device 200 comprises a semiconductor layer 220 having a metal adhesion layer 210 bonded to a planar surface 215 thereof, a porous gold layer 310 bonded to the metal adhesion layer 210 and a gold bond 420 (or bond 605 or bond 910) between a metal layer 410 (or layer 520, or layer 810) and the porous gold layer 310.

In any of the above embodiments of the device 200, the semiconductor layer 220 is one of silicon, lithium niobate or a III-V semiconductor. In some embodiments, the gold bond 420 is part of an electrical interconnection to an electrical component on the semiconductor layer. In some embodiments, the gold bond 420 is part of flip-chip bond between a bond pad 230 on the semiconductor layer 220 and the metal layer 410 on a substrate 520 of the device 200.

Another embodiment is another semiconductor device. With continuing reference to FIGS. 2-10, the device 200 a semiconductor layer 220 having a planar surface 215 with a metal adhesion layer 210 thereon, a metal layer 410 (or layer 520, or layer 810) and a gold bond 420 (or bond 605 or bond 910) between the metal adhesion layer 210 and the metal layer 410. The gold bond 420 includes a non-porous gold interface region 430 adjacent the metal layer 410, the interface region 430 being composed of non-porous gold. The gold bond 420 also includes a porous gold region 440 adjacent the metal adhesion layer 210.

In some such embodiments, the porous gold region includes a plurality of pillars 1010 of gold which are each substantially perpendicularly oriented with respect to the planar surface 215.

Although the present disclosure has been described in detail, those skilled in the art should understand that they can make various changes, substitutions and alterations herein without departing from the scope of the invention.

What is claimed is:

1. A method of manufacturing, comprising:
providing a semiconductor layer having metal adhesion layer on a planar surface of the semiconductor layer and an alloy layer on the metal adhesion layer, the alloy layer comprising an alloy of gold and a non-gold metal;
removing a portion of the non-gold metal from the alloy layer to form a porous gold layer; and
applying pressure between the porous gold layer and a metal layer to form a bond between the semiconductor layer and the metal layer.

2. The method of claim 1, wherein the metal layer is a conductive line or a substrate of a semiconductor device.

3. The method of claim 1, wherein the metal layer is a second metal adhesion layer located on a planar surface of a second semiconductor layer.

4. The method of claim 3, further including:
forming the second metal adhesion layer on the planar surface of the second semiconductor layer;
wherein the applying pressure further includes causing the porous gold layer to contact the second adhesion layer.

5. The method of claim 1, wherein the metal layer is a second porous gold layer located on a planar surface of a second semiconductor layer.

6. The method of claim 5, further including:
forming the second metal adhesion layer on the second semiconductor layer;
forming a second alloy layer on the second metal adhesion layer, the second alloy layer comprising an alloy of gold and a non-gold metal;
removing a portion of the non-gold metal from the second alloy layer to form a second porous gold layer on the second metal adhesion layer; and wherein
the applying pressure includes causing the porous gold layer to contact the second porous gold layer.

7. The method of claim 1, wherein the applying pressure includes producing a pressure between the porous gold and the metal layer of about 600 MPa or less for about 60 seconds or less.

8. The method of claim 1, wherein the applying pressure is performed at a temperature of about 100° C. or less.

9. The method of claim 1, wherein the non-gold metal of the alloy layer includes one or more of silver, zinc, nickel, aluminum, and platinum.

10. The method of claim 1, wherein the non-gold metal is silver.

11. The method of claim 1, wherein the alloy layer has about 20 to about 50 weight percent gold and has a remainder substantially of silver.

12. The method of claim 1, wherein the adhesion layer includes a layer of titanium or chromium on the semiconductor layer.

13. The method of claim 12, wherein the adhesion layer includes a second layer of gold or platinum on the first layer of titanium or chromium.

14. The method of claim 13, wherein the adhesion layer includes a third layer of gold on the second layer of platinum.

15. A semiconductor device, comprising:
a semiconductor layer having a metal adhesion layer bonded to a planar surface thereof;
a porous gold layer bonded to the metal adhesion layer; and
a gold bond between a metal layer and the porous gold layer.

16. The device of claim 15, wherein the semiconductor layer is one of a silicon layer, a lithium niobate layer and a III-V semiconductor layer.

17. The device of claim 15, wherein the gold bond is part of an electrical interconnection to an electrical component on the semiconductor layer.

18. The device of claim 15, wherein the gold bond is part of flip-chip bond between a bond pad of the semiconductor layer and the metal layer on a substrate of the device.

19. An semiconductor device, comprising:
a semiconductor layer having a planar surface with a metal adhesion layer thereon;
a metal layer; and
a gold bond between the metal adhesion layer and the metal layer, the gold bond including:
a non-porous gold interface region adjacent the metal layer, and
a porous gold region adjacent the metal adhesion layer.

20. The device of claim 19, wherein the porous gold region includes a plurality of pillars of gold which are each substantially perpendicularly oriented with respect to the planar surface.
